(19) United States
(12) Patent Application Publication
(10) Pub. No.: US 2011/0254030 A1
(43) Pub. Date: Oct. 20, 2011

(54) LIQUID REFLECTOR

(75) Inventors: Andreas Ahlisch, Munich (DE); Frank Gindele, Schweitenkirchen (DE); Siegmund Kobilke, Ingolstadt (DE)

(73) Assignee: PerkinElmer ELCOS GmbH, Pfaffenhofen (DE)

(21) Appl. No.: 12/760,863

(22) Filed: Apr. 15, 2010

(51) Int. Cl. H01L 33/58; H01L 21/56

(52) U.S. Cl. 257/98; 438/27; 257/E33.056; 257/E33.068; 257/E21.502

(57) ABSTRACT

A light emitting diode (LED) package is disclosed which has an integral reflector for improving performance. The package includes a substrate for supporting the LED. A frame is formed on the top surface of the substrate surrounding the LED. During fabrication, a liquid compound is dispensed into the frame in a manner to surround the LED without covering the active area of the LED. The liquid compound includes particles for scattering light. The top surface of the liquid compound is curved due to surface tension. The curvature remains after the compound is cured. In a preferred embodiment, an encapsulating material is used to cover the LED and the compound. The reflector functions to increase the light output from the LED package.

### BACKGROUND

1. Field

The present invention relates generally to light emitting diode (LED) packages, and more particularly to LED packages having improved features and a process for manufacturing the same.

2. Related Art

Typically, LEDs are encapsulated by a planar layer of silicone, epoxy, or other transparent materials for protection. Because the encapsulation has a higher index of refraction than air, light rays approaching the boundary of the two media at an angle of incidence greater than the critical angle (with respect to the normal to the boundary surface) are totally reflected back into the encapsulation and to the substrate supporting the LED. This optical phenomenon is known as total internal reflection. As a result, a significant amount of light may not pass through the boundary but is absorbed by the LED package.

One method for alleviating the above problem is to use a solid reflector (e.g., a metallic solid reflector) to increase the light output of the LED package. However, a solid reflector can not be located too closely to the LED chip. Typically, wire bonds are soldered to the die and to the metal leads of the chip first, and the solid reflector is then mounted afterwards. The minimal tolerance between the solid reflector and the LED chip is restricted by the presence of the wire bonds within the LED package and the accuracy for the assembling process. For example, the tolerance between the solid reflector and the chip may be between 150-200 micrometers. To avoid damaging the wire bonds, the mounting of the solid reflector onto the LED package needs to be done with high precision, which may be costly and labor intensive. The fabrication of the solid reflector may be costly as well.

Another method for avoiding or reducing total internal reflection is to put a half-ball lens on top of the LED package to increase the light output. However, using half-ball lens has its drawbacks. For example, half-ball lenses do not work well with multi-color LED packages. Due to the image given by the half-ball lens, the light spot appears to have multiple colored smaller light spots inside, which is not acceptable for many applications.

In addition, the increase of the light output of white light LEDs by half-ball lenses strongly depends on the kind of phosphor coating. One way to produce white light using LEDs is to use a converter material, such as phosphor, to convert monochromatic light from a blue LED to broad-spectrum white light. A blue LED may be coated with phosphor. When the phosphor is illuminated by the blue LED, a fraction of the light undergoes the Stokes shift and is transformed from shorter wavelength to longer wavelength light, which is emitted in all directions. Typically, only half of the light emitted by the converter material is transmitted in a forward direction and half is transmitted in a backward direction, i.e., towards the LED chip and the substrate. The emitted light transmitted in the backward direction is mostly absorbed by the substrate. Since a half-ball lens is positioned on top of the LED package, it cannot reduce the light absorbed by the substrate.

In the present application, improved features of LED packages are disclosed. In addition, a process for manufacturing the LED packages is disclosed.

### SUMMARY

A light emitting diode (LED) package is disclosed which has an integral reflector for improving performance. The package includes a substrate for supporting the LED. A frame is formed on the top surface of the substrate surrounding the LED. During fabrication, a liquid compound is dispensed into the frame in a manner to surround the LED without covering the active area of the LED. The liquid compound includes particles that will scatter light. The top surface of the liquid compound is curved due to surface tension. The curvature remains after the compound is cured and defines a reflective upper surface. In a preferred embodiment, an encapsulating material is used to cover the LED and the compound. The reflector functions to increase the light output from the LED package.

### BRIEF DESCRIPTION OF THE FIGURES

The present application can be best understood by reference to the following description taken in conjunction with the accompanying drawing figures, in which like parts may be referred to by like numerals.

FIG. 1 illustrates a cross-sectional view of an exemplary LED package 100 in accordance with the present application.

FIG. 2A illustrates the cross-sectional view of an exemplary LED package 200 along axis C in FIG. 2B.

FIG. 2B illustrates the top view of the exemplary LED package 200.

FIG. 2C illustrates the perspective view of the exemplary LED package 200.

FIG. 2D illustrates the perspective view, partially in section, of the exemplary LED package 200.

FIG. 3 illustrates an exemplary process 300 for manufacturing the exemplary LED package 100 described in the present application.

### DETAILED DESCRIPTION

The following description sets forth numerous specific configurations, parameters, and the like. It should be recognized, however, that such description is not intended as a limitation on the scope of the present invention, but is instead provided as a description of exemplary embodiments.

In the present application, a liquid reflector may be used to increase the light output of an LED package. The liquid reflector may increase the light efficiency of the LED package without using additional optics, such as half-ball lenses and solid reflectors. As a result, some of the drawbacks of using half-ball lenses and solid reflectors may be avoided.

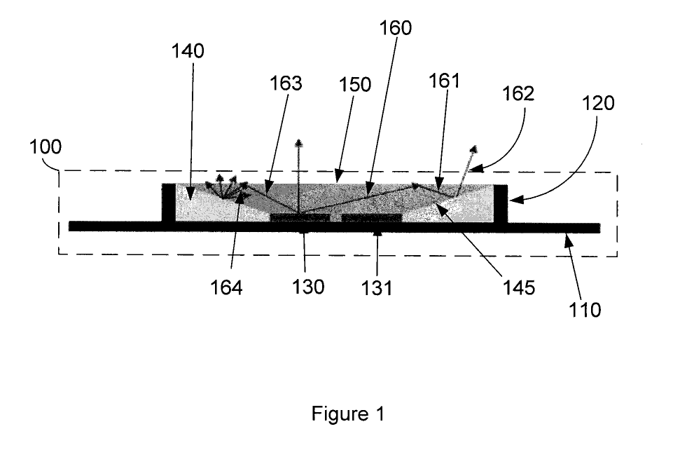

FIG. 1 illustrates a cross-sectional view of an exemplary LED package 100 in accordance with the present application. The LED package 100 comprises a substrate 110, a frame 120, one or more chips (130 and 131), a liquid reflector 140, and an encapsulation 150.

The one or more chips (130 and 131) may be any LED chips. In one exemplary embodiment, the LED package 100 may include a plurality of LED chips, the LED chips being of one or more different colors. For example, the LED package 100 may include one blue, one red, and two green LED chips for multi-color mixing, resulting in a broad-spectrum white light. Further information on such multiple chip packages can be found in U.S. Pat. No. 7,479,660 and US Publication No. 2009/0206758, which are incorporated herein by reference. In another exemplary embodiment, the LED package 100 may include a blue LED coated with phosphor for converting monochromatic blue light into broad-spectrum white light. It is contemplated that the liquid reflector may be used in other light emitting packages with light emitting chips, e.g., lasers and photodiodes.

The LED package 100 includes a substrate 110 for supporting the one or more chips (130 and 131). The substrate 110 may be, but is not limited to, any thin film ceramic substrates, thick film ceramic substrates, isolated metal substrates (IMS), and different kinds of printed circuit boards (PCBs). The substrate 110 may further include die attach pads (not shown) for attaching the one or more chips (130 and 131) onto the substrate 110. For example, a layer of adhesive may be used to attach the one or more chips (130 and 131) onto the die attach pads above the substrate 110. The substrate 110 may also include wire bond pads for attaching wire bonds.

The LED package 100 includes a frame 120 positioned on the top surface of the substrate 110. The frame 120 surrounds the one or more chips (130 and 131). The frame maybe formed integrally with the substrate. Alternatively, the frame 120 may be a separate element attached to the substrate and can made of different materials, including but not limited to plastic, ceramic, and metal. One of the functions of the frame 120 is to act as a mold for forming the liquid reflector 140 and the encapsulation 150. As will be described in greater detail below, the height and shape of the frame 120 may affect the surface curvature of the liquid reflector 140, which may in turn affect the light output and efficiency of the LED package 100. Accordingly, the frame 120 may be a variable form frame. The frame's geometry may be varied according to the specific application. For example, the geometry of the frame 120 may be modified based on different factors, including the number of chips (130 and 131), the size of the light emitting spot, the shape of the liquid reflector, and the like. In one exemplary embodiment, the frame 120 may be a cylinder or a ring positioned on top of the substrate 110, surrounding the one or more chips (130 and 131), wire bonds, wire bond pads, and the like. However, those skilled in the art will recognize that frames in other shapes and sizes may be used as well.

The LED package 100 includes a liquid reflector 140 for increasing the light output. The liquid reflector 140 is formed by dispensing a liquid medium within and bound by the frame 120, In a first preferred embodiment, the liquid medium is filled with particles for scattering light. The liquid medium is then cured to form the liquid reflector 140. As shown in FIG. 1, the liquid reflector 140 covers a portion of the substrate 110 lying between the one or more chips (130 and 131) and the frame 120 without any clearance from the portion of the substrate 110. The liquid reflector 140 surrounds the one or more chips (130 and 131) without covering the active area of the one or more chips (130 and 131). Also as shown in FIG. 1, the shape of the upper surface 145 of the liquid reflector 140 is curved. The curvature is caused by the surface tension or surface energy of the different materials within the liquid medium. It should be recognized that the curvature of surface 145 may be modified by adjusting different factors, including the amount of liquid medium dispensed into the frame 120, the content of the liquid medium, the concentration of the particles, the viscosity of the liquid medium, the geometry (e.g., the height and shape) of the frame 120, the surface roughness of the frame 120, and the like.

The liquid medium may be, but is not limited to, any lacquer, epoxy, silicone, or glue. For example, silicone may be used as the liquid medium. Silicones are mostly two-component (liquid A and liquid B), addition-cure silicone rubber designed for the encapsulation of LEDs, photodiodes, optical waveguide connectors, solar cells, and the like.

Particles are added to the liquid medium for scattering light. The term scattering is used herein its broadest sense to include both specular and diffuse reflections. In a preferred embodiment, the particles suspended in the liquid medium may include aluminum oxide, titanium oxide, silicium oxide, and the like. These particles create diffuse scattering. Alternatively, metal or metal coated particles might be used which reflect light.

In one preferred embodiment, aluminum oxide, titanium oxide, or silicium oxide is suspended in a transparent silicone to form a white silicone liquid medium. For example titanium oxide particles with a diameter of a few micrometers are mixed with a silicone material using e.g., a speed mixer system. The concentration of titanium oxide may be in the range of 5 to 30 percent. The concentration will influence the viscosity and the reflectivity of the liquid reflector. The viscosity can be around 5000 mPa/s and may be adjusted by varying the amount and type of silicone used or the amount of additives (e.g., titanium oxide) added to the silicone.

The silicone material should have a low viscosity to permit good flowability. It should also be transparent and should cure quickly. Table 1 below illustrates some of the desirable properties.

TABLE 1

| | |
|---|---|
| Component A | Component B |

UNCURED PROPERTIES

| | | |
|---|---|---|
| Appearance | Transparent | Transparent |
| Viscosity (23° C.) Pa · s {P} | 7.5 {75} | 1.4 {14} |

| | |
|---|---|
| Mixing ratio by weight | 1:1 |
| Viscosity after mixing (23° C.) Pa · s {P} | 3.2 {32} |
| Pot life (23° C.) h | 8 |
| Refractive index (n_{D}²⁵) | 1.41 |

CURED PROPERTIES (1 h @ 150° C.)

| | |
|---|---|
| Density (23° C.) g/cm³ | 1.05 |
| Hardness (Type A) | 64 |
| Tensile strength MPa {kgf/cm²} | 9.0 {92} |
| Elongation % | 80 |
| Lap share strength* MPa {kgf/cm²} | 1.5 {15} |
| Linear expansion 1/K | 2.8 × 10⁻⁴ |
| Volume resistivity Ω · cm | 1.0 × 10¹⁵ |
| Dielectric strength kV/mm | 20 |
| Dielectric constant (60 Hz) | 2.8 |
| Dissipation factor (60 Hz) | 0.001 |

The LED package 100 includes an encapsulation 150 for protecting the one or more chips (130 and 131), the wire bonds, and the like. The encapsulation 150 covers the liquid reflector 140 and the active area of the one or more chips (130 and 131). The encapsulation 150 may cover a portion of a wire bond without a clearance from the wire bond. The encapsulation 150 may be formed by dispensing an encapsulating material onto the liquid reflector 140 after the reflector has been cured. The encapsulation is then cured. The encapsulation 150 may be a transparent material, such as any lacquer, epoxy, silicone, glue, and the like. It should be recognized in some exemplary embodiments, the LED package 100 may not include an encapsulation 150; the LED package 100 includes a transparent plate (not shown) placed on top of the frame 120 and covering the one or more chips (130 and 131).

The liquid reflector 140 increases the light output of the LED package 100 because light reflected back into the LED package 100 (e.g., from the encapsulation-air boundary due to total internal reflection) is again reflected by the curved surface 145 on the liquid reflector 140 out of the LED package 100. For example, as shown in FIG. 1, a light ray 160 emitting from chip 130 approaches the encapsulation-air boundary at an angle of incidence greater than the critical angle. As a result, the light ray 160 is totally reflected and scattered back into the encapsulation 150 as a light ray 161. As the light ray 161 hits the curved surface 145 on the liquid reflector 140, the light ray 161 is reflected back as a light ray 162, which passes through the boundary and out of the LED package 100. Note that unlike the light ray 160, the light ray 162 reflected by the curved surface 145 has an angle of incidence less than the critical angle, and as a result, the light ray 162 passes through the boundary while the light ray 160 is totally reflected.

The liquid reflector 140 further increases the light output of the LED package 100 because light reflected back into the LED package 100 by total internal reflection is again reflected by the particles of the liquid reflector 140 out of the LED package 100. For example, as shown in FIG. 1, a light ray 163 emitting from chip 130 approaches the encapsulation-air boundary at an angle of incidence greater than the critical angle. As a result, the light ray 163 is totally reflected back into the encapsulation 150 as a light ray 164. As the light ray 164 hits the particles suspended in the liquid reflector 140, the light ray 164 is scattered by the particles as a plurality of reflected light rays, each with a different angle of incidence. Since many of the reflected light rays have angles of incidences less than the critical angle, these reflected light rays pass through the encapsulation—air boundary, thus increasing the light output of the LED package 100.

In addition, unlike solid reflectors and half-ball lenses, the liquid reflector 140 increases the light output of white LEDs as well. As discussed above, when phosphor is illuminated by a blue LED, a fraction of the light undergoes the Stokes shift and is transformed from shorter wavelength to longer wavelength light, which is emitted in all directions. Typically, only half of the emitted light is transmitted in a forward direction and half is transmitted in a backward direction, i.e., towards the chips (130 and 131) and the substrate 110. The emitted light transmitted in the backward direction is mostly absorbed by the substrate 110. Since a half-ball lens is positioned on top of the LED package 100, it cannot reduce the light absorbed by the substrate 110. By contrast, the liquid reflector 140 covers the substrate 110; thus, the particles may scatter the emitted light originally transmitting in the backward direction, thereby altering the light's direction, sending it back out of the LED package 100, and avoiding it from being absorbed by the package 100.

In one exemplary embodiment, an LED package for white emitting LEDs with a liquid reflector achieves approximately 40% greater light output compared with an LED package without any liquid reflector. Further, the liquid reflector 140 has a number of advantages. It increases the light efficiency of the LED package 100 without using additional optics, such as half-ball lenses and solid reflectors, thus making the LED package 100 more cost effective. Unlike solid reflectors, the liquid reflector 140 covers and protects the wire bonds (and other components) without putting high mechanical stress to the wire bonds. There is no minimal tolerance between the liquid reflector 140 and the wire bonds. As a result, cost and labor intensive mounting may be avoided. In addition, with no gaps between the liquid reflector 140 and the one or more chips (130 and 131) and any frame surrounding the LED chips, more light may be reflected by the liquid reflector 140 out of the LED package 100.

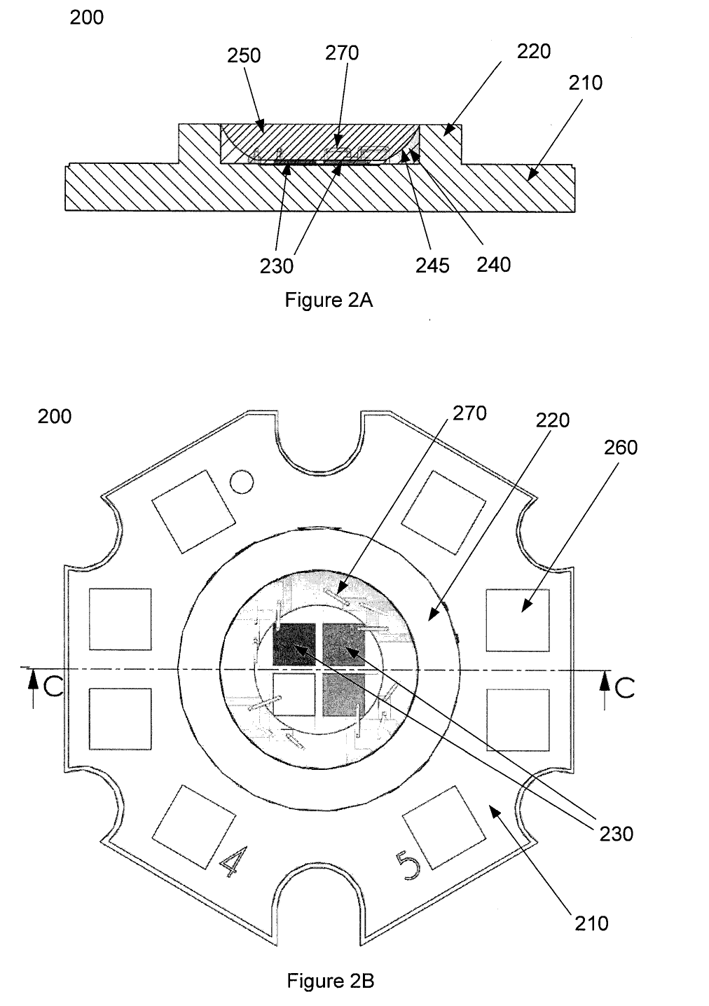

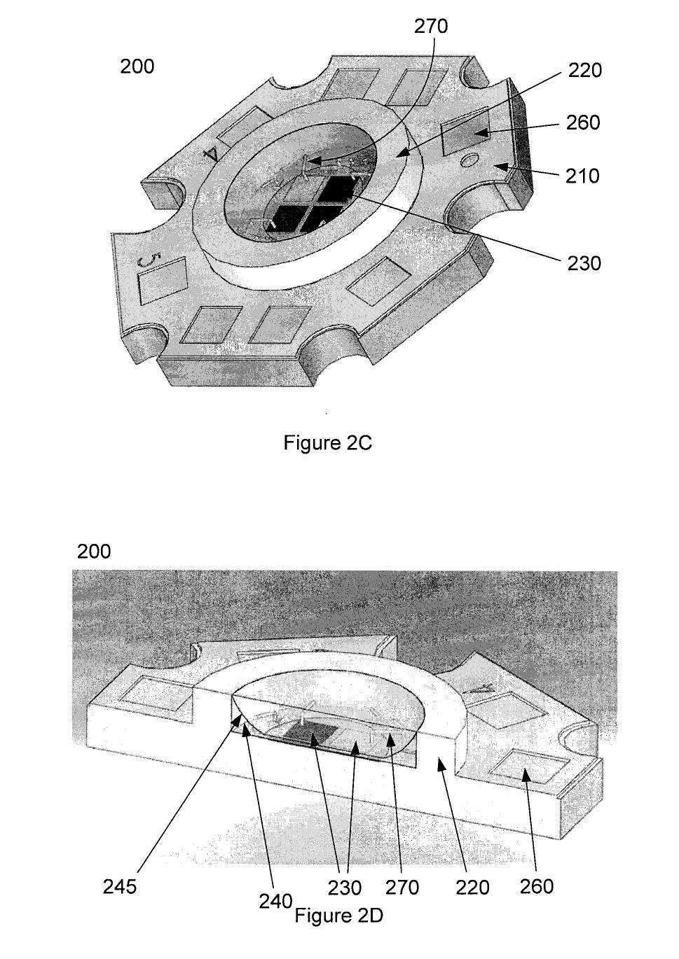

FIGS. 2A-2D illustrate the different views of an exemplary LED package 200 in accordance with the present application. FIG. 2A illustrates the cross-sectional view of the LED package 200 along axis C in FIG. 2B. FIG. 2B illustrates the top view of the LED package 200. FIG. 2C illustrates the perspective view of the LED package 200. FIG. 2D illustrates the perspective view, partially in section, of the LED package 200. The LED package 200 comprises a substrate 210, a frame 220, four LED chips 230, a liquid reflector 240 with a curved surface 245, an encapsulation 250, a plurality of pads 260 for electrical connection, and a plurality of wire bonds 270.

As shown in FIG. 2A, the wire bonds 270 are partially covered by the liquid reflector 240 and partially covered by the encapsulation 250. In this exemplary LED package 200, the frame 220 is a cylinder or a ring positioned on top of the substrate 210, surrounding the LED chips 230, the liquid reflector 240, the encapsulation 250, and the wire bonds 270.

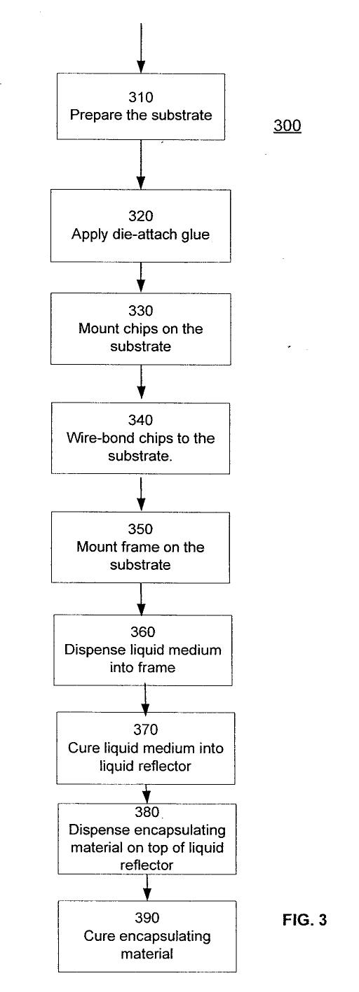

FIG. 3 illustrates an exemplary process 300 for manufacturing the LED package 100 (see FIG. 1) described in the present application. At 310, the substrate 110 is prepared by methods known in the art. The substrate 110 can be, but is not limited to, a thin film ceramic substrate, a thick film ceramic substrate, and any kind of IMS or printed circuit board. At 320, die-attach glue is applied. The glue may be applied with dispensing, stamping, or printing approaches. At 330, the one or more chips (130 and 131) are mounted on the substrate 110 manually or using a semi-automatic or automatic die-attach machine. For example, the chips (130 and 131) are die-bonded and the dies are cured or soldered. At 340, wire bonds are added to the substrate 110 manually or using a semi-automatic or automatic die-attach machine. At 350, the frame 120 is mounted onto the substrate 110 using epoxy or silicone, and the epoxy or silicone is cured. At 360, a liquid medium is dispensed into the frame 120, wherein the liquid medium is filled with particles. At 370, the liquid medium is cured to form the liquid reflector 140. At 380, an encapsulating material is dispensed on top of the liquid reflector 140. At 390, the encapsulation material is cured to form the encapsulation 150.

It should be recognized that process 300 can be preceded by any number of processes performed as part of an assembly process. For example, in one preceding process, the substrate 110 may be processed with cavities and/or embosses for the chips (130 and 131) to sit on. Also, any number of processes may be performed subsequent to process 300 as part of the assembly process. For example, in one subsequent process, the LED packages 100 may be tested in matrix form or individually. It is contemplated that some of the acts described in process 300 may be performed in slightly different orders or may be performed simultaneously. Some of the acts may be skipped. For example, some exemplary embodiments may not include any encapsulation 150. Accordingly, some of the steps in process 300 may be modified or skipped.

In the embodiments discussed above, the reflections at the interface between the reflector 140 and the encapsulation 150 are created by adding particles to the reflector while it is in liquid form, prior to curing. Similar performance could be achieved without adding particles to the reflector if a scattering interface can be created between the top surface of the reflector and the bottom surface of the encapsulation. This type of scattering interface has been observed where the materials used to form the reflector and the encapsulation are different. The exact nature of the scattering interface has not been determined. However, one skilled in the art will understand that that a mismatch of indices of refraction or imperfections such as bubbles at the interface can cause the light to scatter when impinging on the interface.

Although the present invention has been described in connection with some embodiments, it is not intended to be limited to the specific form set forth herein. Rather, the scope of the present invention is limited only by the claims. Additionally, although a feature may appear to be described in connection with particular embodiments, one skilled in the art would recognize that various features of the described embodiments may be combined in accordance with the invention.

Furthermore, although individually listed, a plurality of means, elements or process steps may be implemented by, for example, a single unit or processor. Additionally, although individual features may be included in different claims, these may possibly be advantageously combined, and the inclusion in different claims does not imply that a combination of features is not feasible and/or advantageous. Also, the inclusion of a feature in one category of claims does not imply a limitation to this category, but rather the feature may be equally applicable to other claim categories, as appropriate.

What is claimed is:

1. A light emitting package comprising:
a light emitting chip;
a substrate supporting the light emitting chip;
a frame positioned on the top surface of the substrate, wherein the light emitting chip is surrounded by the frame; and
a reflector material covering a portion of the substrate lying between the frame and the light emitting chip, the reflector material surrounding the light emitting chip without covering the active area of the light emitting chip, the reflector material having an curved top surface, the reflector material being formed from a compound which is initially in liquid form and is thereafter cured to a solid form, and wherein the compound includes a plurality of particles for scattering light.

2. The light emitting package of claim 1, further including an encapsulation covering the light emitting chip.

3. The light emitting package of claim 2, wherein the reflector material is formed by dispensing the compound in liquid form within and bound by the frame and curing the compound.

4. The light emitting package of claim 2, wherein the curvature of the curved top surface is caused by surface tension of the compound.

5. The light emitting package of claim 2, wherein the curvature of the curved top surface is adjustable by varying a factor selected from the group consisting of the amount of the compound, the content of the compound, the concentration of the particles, the viscosity of the compound, the curing conditions, the geometry of the frame and substrate, and the surface roughness or surface tension of the frame and substrate.

6. The light emitting package of claim 2, wherein the compound is selected from the group consisting of lacquer, epoxy, silicone, and glue.

7. The light emitting package of claim 2, wherein the plurality of particles is made of a material selected from the group consisting of aluminum oxide, titanium oxide, and silicium oxide.

8. The light emitting package of claim 2, wherein the curved top surface reflects light that is reflected back into the light emitting package by total internal reflection.

9. The light emitting package of claim 2, wherein the frame is made of a material selected from the group consisting of polymer, plastic, ceramic, and metal.

10. The light emitting package of claim 2, wherein the encapsulation covers the reflector material and the active area of the light emitting chip.

11. The light emitting package of claim 2, wherein the encapsulation is formed by dispensing an encapsulating material within and bound by the frame and curing the encapsulating material.

12. The light emitting package of claim 11, wherein the encapsulating material is selected from the group consisting of lacquer, epoxy, silicone, and glue.

13. The light emitting package of claim 2, further including a wire bond, wherein the reflector material covers a portion of the wire bond without a clearance from the wire bond.

14. The light emitting package of claim 1, wherein the light emitting chip is an LED chip.

15. The light emitting package of claim 1, wherein the substrate is selected from the group consisting of thin film ceramic substrates, thick film ceramic substrates, isolated metal substrates, and printed circuit boards.

16. A light emitting package comprising:
a light emitting chip;
a substrate supporting the light emitting chip;
a frame positioned on the top surface of the substrate, wherein the light emitting chip is surrounded by the frame;
a reflector material covering a portion of the substrate lying between the frame and the light emitting chip, the reflector material surrounding the light emitting chip without covering the active area of the light emitting chip, the reflector material having an curved top surface, the reflector material being formed from a compound which is initially in liquid form and is thereafter cured to a solid form, and wherein the compound includes a plurality of particles for scattering light; and
a transparent plate placed on top of the frame and covering the light emitting chip.

17. A method of fabricating a light emitting diode (LED) package of the type having an LED chip attached to the top surface of a substrate, comprising the steps of:
forming a frame on the top surface of the substrate, the frame surrounding the LED chip;
dispensing a compound in liquid form within and bounded by the frame in a manner to surround the LED chip without covering the active area of the LED chip, said compound including particles for scattering light;
curing the compound to define a reflector element having a curved top reflective surface;
dispensing an encapsulating material to cover the LED chip and the curved top reflective surface; and
curing the encapsulating material.

18. The method of claim 17, wherein the curved top reflective surface reflects light out of the LED package.

19. The process of claim 17, wherein the particles diffusely scatter light in different directions out of the LED package.

20. A light emitting package comprising:
a light emitting chip;
a substrate supporting the light emitting chip;
a frame positioned on the top surface of the substrate, wherein the light emitting chip is surrounded by the frame;
a material covering a portion of the substrate lying between the frame and the light emitting chip, the reflector material surrounding the light emitting chip without covering the active area of the light emitting chip, the material having an curved top surface, the reflector material being formed from a compound which is initially in liquid form and is thereafter cured to a solid form; and
an encapsulation covering the light emitting chip, wherein a scattering interface is formed between the curved top surface of the material and the bottom surface of the encapsulation.

21. A method of fabricating a light emitting diode (LED) package of the type having an LED chip attached to the top surface of a substrate, comprising the steps of:
forming a frame on the top surface of the substrate, the frame surrounding the LED chip;
dispensing a compound in liquid form within and bounded by the frame in a manner to surround the LED chip without covering the active area of the LED chip,
curing the compound to define an element having a curved top surface;
dispensing an encapsulating material to cover the LED chip and the curved top surface; and
curing the encapsulating material wherein a scattering interface is formed between the curved top surface of the material and the bottom surface of the encapsulation.
